(19) United States
(12) Patent Application Publication
(10) Pub. No.: US 2025/0143148 A1
(43) Pub. Date: May 1, 2025

(54) DISPLAY DEVICE

(71) Applicant: Samsung Display Co., LTD., Yongin-si (KR)

(72) Inventors: Hee Kwang SONG, Yongin-si (KR); Hee Kyung KIM, Yongin-si (KR)

(73) Assignee: Samsung Display Co., LTD., Yongin-si (KR)

(21) Appl. No.: 18/734,446

(22) Filed: Jun. 5, 2024

(30) Foreign Application Priority Data
Nov. 1, 2023 (KR) 10-2023-0148843

(51) Int. Cl. H10K 59/80; H10K 59/35

(52) U.S. Cl. CPC H10K 59/877; H10K 59/35

(57) ABSTRACT

A display device is provided. The display device includes light emitting areas and a non-light emitting area, a substrate, a light emitting element layer disposed on the substrate, a thin film encapsulation layer disposed on the light emitting element layer, a wavelength conversion layer disposed on the thin film encapsulation layer, a counter substrate facing the substrate, a color filter layer disposed on a surface of the counter substrate, and a filling layer filled between the color filter layer and the wavelength conversion layer, the filling layer including filling particles.

### CROSS-REFERENCE TO RELATED APPLICATION(S)

This application claims priority to and benefits of Korean Patent Application No. 10-2023-0148843 under 35 U.S.C. § 119 filed on Nov. 1, 2023, in the Korean Intellectual Property Office, the entire contents of which are incorporated herein by reference.

### BACKGROUND

### 1. Technical Field

The disclosure relates to a display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

The display device may be a flat panel display device such as a liquid crystal display device, a field emission display device, or a light emitting display device. The light emitting display device may include an organic light emitting display device including an organic light emitting element, an inorganic light emitting display device including an inorganic light emitting element such as an inorganic semiconductor, and a subminiature light emitting display device including a subminiature light emitting element.

The organic light emitting element may include two opposing electrodes and a light emitting layer disposed therebetween. The light emitting layer receives electrons and holes from the two electrodes and recombines the electronic and the holes to generate excitons, and the generated excitons change from an excited state to a ground state, thereby emitting light.

The organic light emitting display device including the organic light emitting element may be configured in a light weight and thin shape with low power consumption because of not requiring a light source such as a backlight unit, and has also attracted attention as a next-generation display device because of having high-quality characteristics such as a wide viewing angle, high luminance and contrast, and a fast response speed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure a display device capable of reducing manufacturing costs by simplifying a structure thereof.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device may include light emitting areas and a non-light emitting area; a substrate; a light emitting element layer disposed on the substrate; a thin film encapsulation layer disposed on the light emitting element layer; a wavelength conversion layer disposed on the thin film encapsulation layer; a counter substrate facing the substrate; a color filter layer disposed on a surface of the counter substrate; and a filling layer filled between the color filter layer and the wavelength conversion layer, the filling layer including filling particles.

In an embodiment, the light emitting areas may include a first light emitting area, a second light emitting area, and a third light emitting area, and the wavelength conversion layer may include a first wavelength conversion pattern overlapping the first light emitting area and a second wavelength conversion pattern overlapping the second light emitting area.

In an embodiment, the wavelength conversion layer may include a capping layer covering the first wavelength conversion pattern, the second wavelength conversion pattern, and the thin film encapsulation layer, and the capping layer is disposed closer to the substrate in the third light emitting area than the first light emitting area and the second light emitting area.

In an embodiment, the filling layer may include a filling resin in which the filling particles are dispersed, and a content of the filling particles is in a range of about 1 wt % to about 10 wt %.

In an embodiment, the filling particles may include light scattering particles.

In an embodiment, the filling particles may be at least one selected from the group consisting of silica (SiO₂), alumina, silicon, titanium oxide (TiO₂), zirconia oxide (ZrO₂), barium sulfate, zinc oxide (ZnO), and polymethyl methacrylate (PMMA).

In an embodiment, a thickness of the filling layer may be in a range of about 0.1 μm to about 10 μm.

In an embodiment, a refractive index of the filling resin of the filling layer may be in a range of about 1.4 to about 1.7.

In an embodiment, a thickness of the filling layer measured in a vertical direction in one of the light emitting areas may be different from a thickness of the filling layer measured in the vertical direction in the other one of the light emitting areas.

In an embodiment, a thickness of the filling layer measured in a vertical direction in the third light emitting area may be greater than a thickness of the filling layer measured in the vertical direction in the first light emitting area or the second light emitting area.

In an embodiment, the display device may further comprise a spacer disposed between the wavelength conversion layer and the color filter layer.

In an embodiment, the spacer may overlap the non-light emitting area and may not overlap the light emitting area.

In an embodiment, a thickness of the spacer may be in a range of about 0.1 μm to about 4.5 μm.

In an embodiment, a planar shape of the spacer may be a substantially mesh shape or a dot shape.

According to an aspect of the disclosure, a display device may include light emitting areas and a non-light emitting area; a substrate; a light emitting element layer disposed on the substrate; a thin film encapsulation layer disposed on the light emitting element layer; a wavelength conversion layer disposed on the thin film encapsulation layer; a counter substrate facing the substrate; a color filter layer disposed on a surface of the counter substrate; and a filling layer filled between the color filter layer and the wavelength conversion layer, the filling layer including filling particles, wherein the color filter layer and the wavelength conversion layer contact each other.

In an embodiment, the filling layer may include a first filling pattern, a second filling pattern, and a third filling pattern that overlap the light emitting areas and are spaced apart from each other.

In an embodiment, the light emitting areas may include a first light emitting area, a second light emitting area, and a third light emitting area, and the first filling pattern overlaps the first light emitting area, the second filling pattern overlaps the second light emitting area, and the third filling pattern overlaps the third light emitting area.

In an embodiment, a thickness of the third filling pattern may be greater than a thickness of the first filling pattern or a thickness of the second filling pattern.

In an embodiment, the filling particles may include light scattering particles and at least one selected from the group consisting of silica (SiO₂), alumina, silicon, titanium oxide (TiO₂), zirconia oxide (ZrO₂), barium sulfate, zinc oxide (ZnO), and polymethyl methacrylate (PMMA).

In an embodiment, the filling layer may include a filling resin in which the filling particles are dispersed, and a refractive index of the filling resin is in a range of about 1.4 to about 1.7.

In the display device according to an embodiment, a pattern with a separate light scattering function may be omitted in a third light emitting area by forming a filling layer including filling particles that scatter light between a wavelength conversion layer and a color filter layer. Accordingly, manufacturing costs according to a mask process may be reduced and a process may be simplified.

As the filling layer is disposed throughout a display area, a light scattering effect may be applied to the third light emitting area in which light is emitted without light conversion in the wavelength conversion layer, thereby increasing a positive side luminance ratio.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic plan view illustrating lines included in the display device according to an embodiment;

FIG. 3 is schematic diagram of an equivalent circuit diagram of one sub-pixel according to an embodiment;

FIG. 4 is a schematic cross-sectional view schematically illustrating the display device according to an embodiment;

FIG. 5 is a schematic cross-sectional view schematically illustrating the display device according to an embodiment;

FIG. 6 is a schematic cross-sectional view illustrating a filling layer of the display device according to an embodiment;

FIGS. 7 to 9 are schematic cross-sectional views illustrating a method for manufacturing a display device according to an embodiment for each process;

FIG. 10 is a schematic cross-sectional view illustrating a display device according to an embodiment;

FIG. 11 is a schematic plan view illustrating each light emitting area and a non-light emitting area of the display device according to an embodiment;

FIG. 12 is a schematic cross-sectional view illustrating a display device according to an embodiment;

FIG. 13 is a schematic plan view illustrating an example of a spacer of the display device according to an embodiment; and

FIG. 14 is a schematic plan view illustrating another example of the spacer of the display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Each of the features of the various embodiments of the disclosure may be combined or combined with each other, in part or in whole, and technically various other embodiments are possible. Each embodiment may be implemented independently of each other or may be implemented together in an association.

Hereinafter, embodiments of the disclosure will be described with reference to the accompanying drawings.

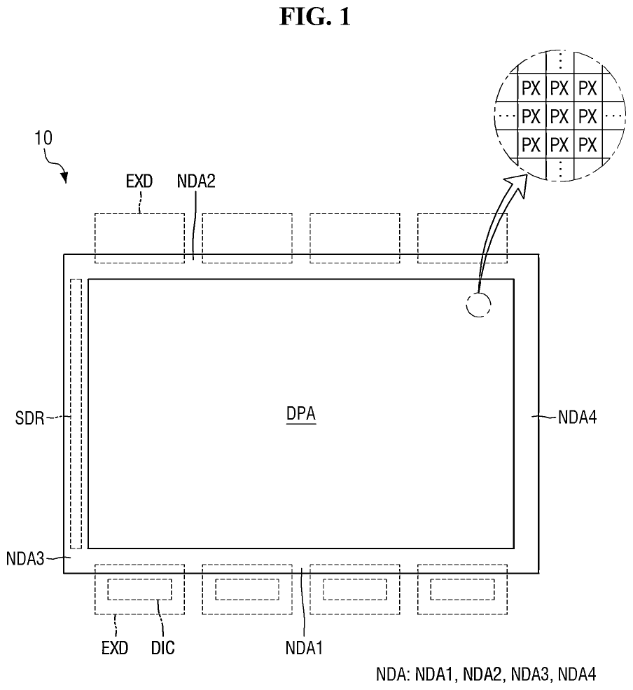

FIG. 1 is a schematic plan view of a display device according to an embodiment.

Referring to FIG. 1, a display device 10 according to an embodiment may be applied to smartphones, mobile phones, tablet personal computers (PCs), personal digital assistants (PDAs), portable multimedia players (PMPs), televisions, game machines, wrist watch-type electronic devices, head-mounted displays, monitors of personal computers, laptop computers, car navigation systems, vehicle instrument boards, digital cameras, camcorders, external billboards, electric signs, medical devices, inspection devices, various home appliances such as refrigerators and washing machines, or Internet of Things (IoT) devices. In the specification, a television (TV) will be described as an example of the display device 10, and the TV may have high resolution or ultra-high resolution such as high definition (HD), ultra-high definition (UHD), 4K, or 8K.

The display device 10 according to an embodiment may be variously classified according to a display method. For example, the classification of the display device 10 may include an organic light emitting display (OLED), an inorganic light emitting display (inorganic EL), a quantum dot light emitting display (QED), a micro LED, a nano LED, a plasma display panel (PDP), a field emission display (FED), a cathode ray tube display (CRT), a liquid crystal display (LCD), an electrophoretic display (EPD), and the like within the spirit and the scope of the disclosure. In the following, an organic light emitting display device and an inorganic light emitting display device will be described as an example of the display device 10, and unless a special distinction is required, an organic light emitting display device applied to an embodiment will be simply abbreviated as a display device. However, an embodiment is not limited to the organic light emitting display device or the inorganic light emitting display device, and other display devices listed above or known in the art may also be applied within the scope of sharing technical ideas.

The display device 10 according to an embodiment may have a square shape in plan view, for example, a rectangular shape. In case that the display device 10 is a television, the display device 10 is disposed so that a long side thereof is positioned in a horizontal direction. However, the disclosure is not limited thereto, and the long side of the display device 10 may be positioned in a vertical direction, and the display device 10 may be rotatably installed, so that the long side of the display device 10 may also be variably positioned in the horizontal or vertical direction.

The display device 10 may include a display area DPA and a non-display area NDA. The display area DPA may be an active area in which an image is displayed. The display area DPA may have a rectangular shape in plan view, similar to the overall shape of the display device 10, but is not limited thereto.

The display area DPA may include a plurality of pixels PX. The plurality of pixels PX may be arranged or disposed in a matrix direction. A shape of each pixel PX may be a rectangular shape or a square shape in plan view, but is not limited thereto, and may also be a rhombic shape of which each side is inclined with respect to a direction of one side or a side of the display device 10. The plurality of pixels PX may include multiple color pixels PX. For example, the plurality of pixels PX may include, but are not limited to, a first color pixel PX of red, a second color pixel PX of green, and a third color pixel PX of blue. Each color pixel PX may be alternately arranged or disposed in a stripe type or PENTILE™ type.

The non-display area NDA may be disposed around the display area DPA. The non-display area NDA may entirely or partially surround the display area DPA. The display area DPA may have a rectangular shape, and the non-display area NDA may be disposed adjacent to four sides of the display area DPA. The non-display area NDA may constitute a bezel of the display device 10.

A driving circuit or a driving element for driving the display area DPA may be disposed in the non-display area NDA. In an embodiment, pad portions may be provided on a display substrate of the display device 10 in a first non-display area NDA1 disposed adjacent to a first long side (lower side in FIG. 1) of the display device 10 and a second non-display area NDA2 disposed adjacent to a second long side (upper side in FIG. 1) of the display device 10, and external devices EXD may be mounted on pad electrodes of the pad portions. Examples of the external devices EXD may include a connection film, a printed circuit board, a driving chip (DIC), a connector, a line connection film, and the like within the spirit and the scope of the disclosure. A scan driver SDR and the like formed directly on the display substrate of the display device 10 may be disposed in a third non-display area NDA3 disposed adjacent to a first short side (left side in FIG. 1) of the display device 10. However, the disclosure is not limited thereto, and the scan driver SDR may also be disposed on a second short side (right side in FIG. 1) of the display device 10. FIG. 1 may also include a fourth non-display area NDA4.

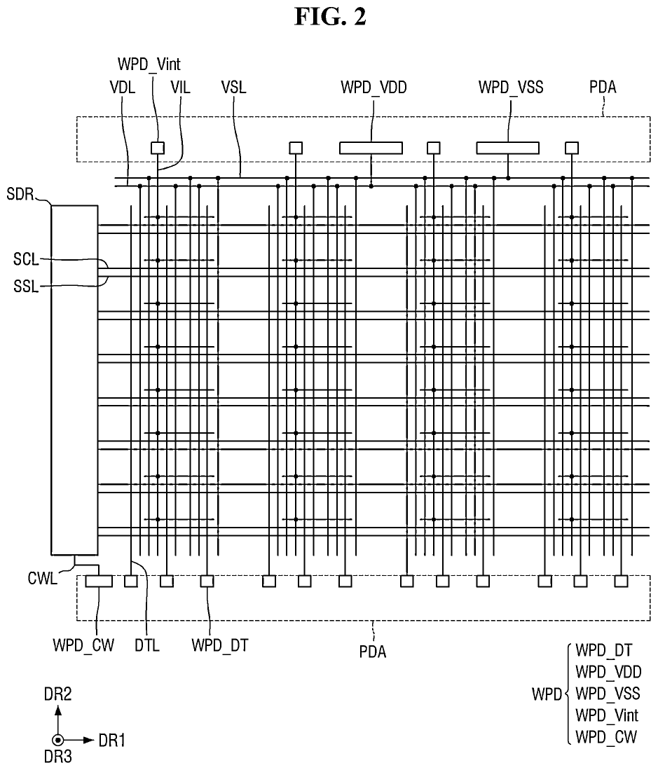

FIG. 2 is a schematic plan view illustrating lines included in the display device according to an embodiment.

Referring to FIG. 2, the display device 10 may include a plurality of lines. The plurality of lines may include a scan line SCL, a sensing line SSL, a data line DTL, an initialization voltage line VIL, a first voltage line VDL, and a second voltage line VSL. Although not illustrated in the drawing, other lines may be further disposed in the display device 10.

The scan line SCL and the sensing line SSL may extend in a first direction DR1. The scan line SCL and the sensing line SSL may be connected to the scan driver SDR. The scan driver SDR may include a driving circuit. The scan driver SDR may be disposed on one side or a side of the display area DPA in the first direction DR1, but is not limited thereto. The scan driver SDR may be connected to a signal connection line CWL, and at least one end of the signal connection line CWL may be connected to an external device by forming a pad WPD_CW on a pad area PDA of the non-display area.

In the specification, the meaning of ‘connection’ may mean that any one member is connected to another member through mutual physical contact, as well as that any one member is connected to another member through the other member. It may be understood that any one portion and another portion as one integrated member are interconnected due to the integrated member. Furthermore, the connection between any one member and another member may be interpreted as the meaning including an electrical connection through the other member in addition to a connection through direct contact therebetween.

The data line DTL and the initialization voltage line VIL may extend in a second direction DR2 intersecting the first direction DR1. The initialization voltage line VIL may further include a portion extending in the second direction DR2 and a portion branching therefrom in the first direction DR1. The first voltage line VDL and the second voltage line VSL may also include portions extending in the second direction DR2 and portions connected thereto and extending in the first direction DR1. The first voltage line VDL and the second voltage line VSL may have a mesh structure, but are not limited thereto. Although not illustrated in the drawing, each of the pixels PX of the display device 10 may be connected to one or more data lines DTL, initialization voltage lines VIL, first voltage lines VDL, and second voltage lines VSL.

The data line DTL, the initialization voltage line VIL, the first voltage line VDL, and the second voltage line VSL may be electrically connected to at least one line pad WPD. Each line pad WPD may be disposed in the pad area PDA. In an embodiment, a line pad WPD_DT (hereinafter, referred to as ‘data pad’) of the data line DTL may be disposed in a pad area PDA on one side or a side of the display area DPA in the second direction DR2, and a line pad WPD_Vint (hereinafter, ‘initialization voltage pad’) of the initialization voltage line VIL, a line pad WPD_VDD (hereinafter, a ‘first power pad’) of the first voltage line VDL, and a line pad WPD_VSS (hereinafter, ‘second power pad’) of the second voltage line VSL may be disposed in a pad area PDA positioned on the other side of the display area DPA in the second direction DR2. As another example, the data pad WPD_DT, the initialization voltage pad WPD_Vint, the first power pad WPD_VDD, and the second power pad WPD_VSS may all be disposed in the same area, for example, in the non-display area NDA positioned on an upper side of the display area DPA. The external device EXD may be mounted on the line pad WPD. The external device EXD may be mounted on the line pad WPD through an anisotropic conductive film, ultrasonic bonding, or the like within the spirit and the scope of the disclosure.

Each pixel PX or sub-pixel SPX of the display device 10 may include a pixel driving circuit. The above-described lines may apply a driving signal to each pixel driving circuit while passing through each pixel PX or passing around each pixel PX. The pixel driving circuit may include a transistor and a capacitor. The numbers of transistors and capacitors in each pixel driving circuit may be variously changed. According to an embodiment, each sub-pixel SPXn of the display device 10 may have a 3T1C structure in which the pixel driving circuit may include three transistors and one capacitor. Hereinafter, the pixel driving circuit will be described using the 3T1C structure as an example, but the disclosure is not limited thereto, and various other modified pixel PX structures such as a 2T1C structure, a 7T1C structure, and a 6T1C structure may also be applied.

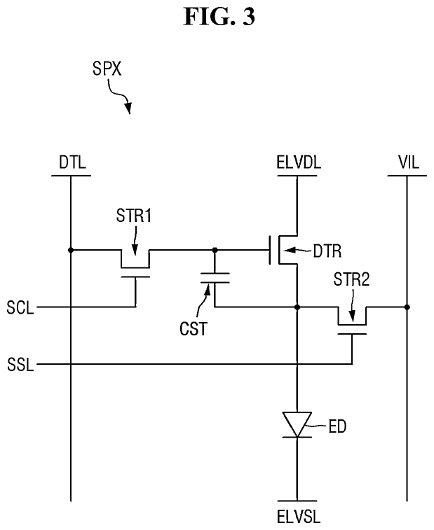

FIG. 3 is an equivalent circuit diagram of one sub-pixel according to an embodiment.

Referring to FIG. 3, each sub-pixel SPX of the display device 10 according to an embodiment may include three transistors DTR, STR1, and STR2 and one storage capacitor CST, in addition to a light emitting element ED.

The light emitting element ED emits light according to a current supplied through a driving transistor DTR. The light emitting element ED may be implemented as an inorganic light emitting diode, an organic light emitting diode, a micro light emitting diode, a nano light emitting diode, or the like within the spirit and the scope of the disclosure.

A first electrode (for example, an anode electrode) of the light emitting element ED may be connected to a source electrode of the driving transistor DTR, and a second electrode (for example, a cathode electrode) of the light emitting element ED may be connected to a second power line ELVSL to which a low potential voltage (second power voltage) lower than a high potential voltage (first power voltage) of a first power line ELVDL is supplied.

The driving transistor DTR adjusts a current flowing from the first power line ELVDL to which the first power is supplied to the light emitting element ED according to a voltage difference between a gate electrode and the source electrode thereof. The gate electrode of the driving transistor DTR may be connected to a first electrode of a first transistor STR1, the source electrode of the driving transistor DTR may be connected to the first electrode of the light emitting element ED, and a drain electrode of the driving transistor DTR may be connected to the first power line ELVDL to which the first power voltage is applied.

The first transistor STR1 is turned on by a scan signal of the scan line SCL and connects the data line DTL to the gate electrode of the driving transistor DTR. A gate electrode of the first transistor STR1 may be connected to the scan line SCL, the first electrode of the first transistor STR1 may be connected to the gate electrode of the driving transistor DTR, and a second electrode of the first transistor STR1 may be connected to the data line DTL.

A second transistor STR2 is turned on by a sensing signal of the sensing signal line SSL and connects the initialization voltage line VIL to the source electrode of the driving transistor DTR. A gate electrode of the second transistor STR2 may be connected to the sensing signal line SSL, a first electrode of the second transistor STR2 may be connected to the initialization voltage line VIL, and a second electrode of the second transistor STR2 may be connected to the source electrode of the driving transistor DTR.

In an embodiment, the first electrode of each of the first and second transistors STR1 and STR2 may be a source electrode, and the second electrode of each of the first and second transistors STR1 and STR2 may be a drain electrode, but the disclosure is not limited thereto, and vice versa.

A capacitor CST is formed between the gate electrode and the source electrode of the driving transistor DTR. The storage capacitor CST stores a difference voltage between a gate voltage and a source voltage of the driving transistor DTR.

The driving transistor DTR and the first and second switching transistors STR1 and STR2 may be formed as thin film transistors. It is described in FIG. 3 that the driving transistor DTR and the first and second switching transistors STR1 and STR2 are N-type metal oxide semiconductor field effect transistors (MOSFETs), but the disclosure is not limited thereto. For example, the driving transistor DTR and the first and second switching transistors STR1 and STR2 may be P-type MOSFETs, or some thereof may be N-type MOSFETs and others thereof may be P-type MOSFETs.

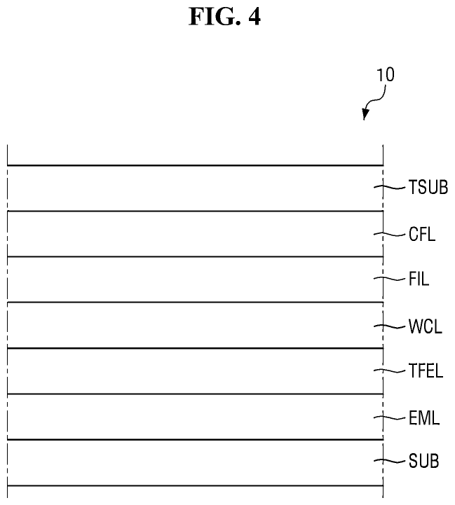

FIG. 4 is a schematic cross-sectional view schematically illustrating the display device according to an embodiment.

Referring to FIG. 4, the display device 10 according to an embodiment may include a substrate SUB, a light emitting element layer EML, a thin film encapsulation layer TFEL, a wavelength conversion layer WCL, a filling layer FIL, a color filter layer CFL, and a counter substrate TSUB.

The substrate SUB may be an insulating substrate. The substrate SUB may include a transparent material. For example, the substrate SUB may include a transparent insulating material such as glass or quartz. The substrate SUB may be a rigid substrate. The substrate SUB is not limited thereto, and may also include plastic such as polyimide and may also have flexible properties capable of being curved, bent, folded, or rolled.

The light emitting element layer EML may be disposed on the substrate SUB. The light emitting element layer EML may include a plurality of switching elements and a plurality of light emitting elements ED disposed in each sub-pixel. The plurality of switching elements may drive the plurality of light emitting elements ED to emit light from the plurality of light emitting elements ED.

The thin film encapsulation layer TFEL may be disposed on the light emitting element layer EML. The thin film encapsulation layer TFEL may include an organic film disposed between a plurality of inorganic films, thereby protecting the light emitting element layer EML from external moisture and oxygen.

The wavelength conversion layer WCL may be disposed on the thin film encapsulation layer TFEL. The wavelength conversion layer WCL may convert a wavelength of light emitted from the light emitting element layer EML to emit red light, green light, and blue light.

The filling layer FIL may be disposed on the wavelength conversion layer WCL. The filling layer FIL may improve light efficiency by totally reflecting light emitted from the wavelength conversion layer WCL at an interface with the wavelength conversion layer WCL. The filling layer FIL may include a low-refractive material, etc., according to embodiments described later. FIL may also include first, second, and third filling patterns, FIP1, FIP2, and FIP3, respectively.

The color filter layer CFL may be disposed on the filling layer FIL. The color filter layer CFL may filter light incident from the outside to reduce reflection of external light and improve color characteristics of light emitted through the wavelength conversion layer WCL.

The counter substrate TSUB may be disposed on the color filter layer CFL. The counter substrate TSUB may encapsulate the light emitting element layer EML together with the substrate SUB. The counter substrate TSUB may include a transparent material. For example, the counter substrate TSUB may include a transparent insulating material such as glass or quartz.

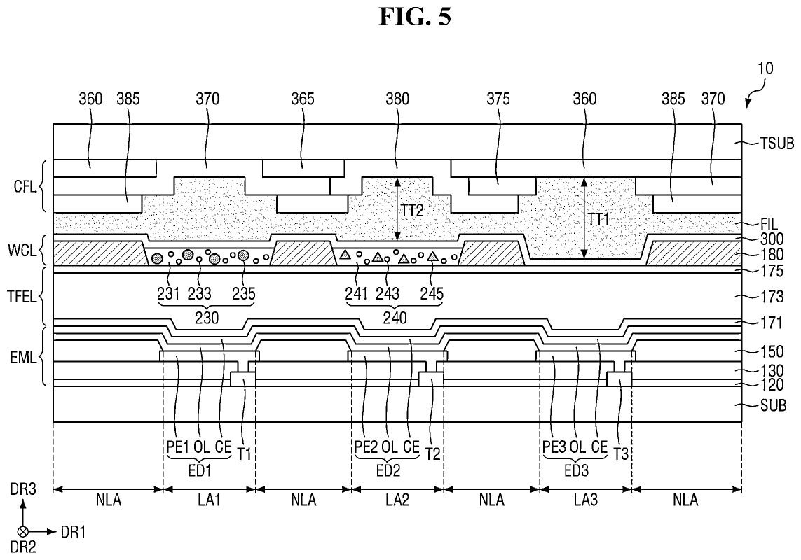

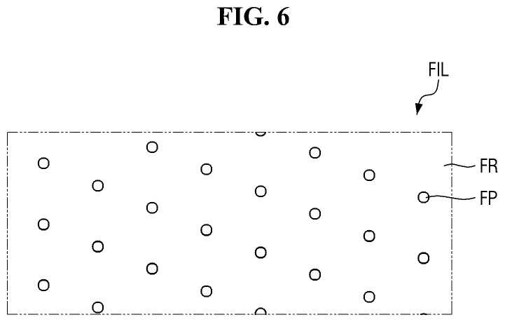

FIG. 5 is a schematic cross-sectional view schematically illustrating the display device according to an embodiment. FIG. 6 is a schematic cross-sectional view illustrating a filling layer of the display device according to an embodiment.

Referring to FIGS. 5 and 6, the display device 10 according to an embodiment may include a substrate SUB, a light emitting element layer EML, a thin film encapsulation layer TFEL, a wavelength conversion layer WCL, a filling layer FIL, a color filter layer CFL, and a counter substrate TSUB.

A plurality of light emitting areas LA1, LA2, and LA3 and a non-light emitting area NLA may be defined in the substrate SUB. The plurality of light emitting areas LA1, LA2, and LA3 may be areas where light generated by light emitting elements ED1, ED2, and ED3 is emitted to the outside, and the non-light emitting area NLA may be an area where light is not emitted to the outside. In an embodiment, a first light emitting area LA1, a second light emitting area LA2, and a third light emitting area LA3 may be sequentially disposed along the first direction DR1 in the display area DPA.

The first light emitting area LA1, the second light emitting area LA2, and the third light emitting area LA3 may have the same width measured in the first direction DR1. However, the disclosure is not limited thereto, and the first light emitting area LA1, the second light emitting area LA2, and the third light emitting area LA3 may have different widths measured in the first direction DR1. For example, the width of the third light emitting area LA3 may be smaller than the width of the second light emitting area LA2, and the width of the second light emitting area LA2 may be smaller than the width of the first light emitting area LA1

Each of the light emitting areas LA1, LA2, and LA3 may emit light of different colors. In an embodiment, the first light emitting area LA1 may emit light of a first color, the second light emitting area LA2 may emit light of a second color, and the third light emitting area LA3 may emit light of a third color. In an embodiment, the light of the first color may be red light with a peak wavelength in the range of about 610 nm to about 650 nm, the light of the second color may be green light with a peak wavelength in the range of about 510 nm to about 550 nm, and the light of the third color may be blue light with a peak wavelength in the range of about 440 nm to about 480 nm. However, the disclosure is not limited thereto, and the light of the first color may also be green light and the light of the second color may also be red light.

Switching elements T1, T2, and T3 may be disposed on the substrate SUB. In an embodiment, a first switching element T1 may be positioned in the first light emitting area LA1 of the substrate SUB, a second switching element T2 may be positioned in the second light emitting area LA2 thereof, and a third switching element T3 may be positioned in the third light emitting area LA3 thereof. However, the disclosure is not limited. In an embodiment, at least one of the first switching element T1, the second switching element T2, and the third switching element T3 may also be positioned in the non-light emitting area NLA.

According to an embodiment, each of the first switching element T1, the second switching element T2, and the third switching element T3 may be a thin film transistor including amorphous silicon, polysilicon, or an oxide semiconductor. Although not illustrated in the drawings, a plurality of signal lines (for example, a gate line, a data line, a power line, etc.) transmitting a signal to each switching element may be further disposed on the substrate SUB. Each of the switching elements T1, T2, and T3 may include a first insulating layer 120. For example, the first insulating layer 120 may be a gate insulating film or an interlayer insulating film of a thin film transistor. The gate insulating film or the interlayer insulating film may be made of a single layer or a multilayer thereof including any one of silicon oxide (SiOₓ), silicon nitride oxide (SiOₓN_{y}), and silicon nitride (SiNₓ).

A second insulating layer 130 may be positioned on the first switching element T1, the second switching element T2, and the third switching element T3. In an embodiment, the second insulating layer 130 may be a planarization film. In an embodiment, the second insulating layer 130 may be made of an organic film. For example, the second insulating layer 130 may include an acrylic resin, an epoxy resin, an imide resin, an ester resin, and the like within the spirit and the scope of the disclosure. In an embodiment, the second insulating layer 130 may include a positive photosensitive material or a negative photosensitive material.

A first pixel electrode PE1, a second pixel electrode PE2, and a third pixel electrode PE3 may be positioned on the second insulating layer 130. The first pixel electrode PE1 may be positioned in the first light emitting area LA1, but at least a portion thereof may extend to the non-light emitting area NLA. The second pixel electrode PE2 may be positioned in the second light emitting area LA2, but at least a portion thereof may extend to the non-light emitting area NLA. The third pixel electrode PE3 may be positioned in the third light emitting area LA3, but at least a portion thereof may extend to the non-light emitting area NLA. The first pixel electrode PE1 may penetrate through the second insulating layer 130 and be connected to the first switching element T1, the second pixel electrode PE2 may penetrate through the second insulating layer 130 and be connected to the second switching element T2, and the third pixel electrode PE3 may penetrate through the second insulating layer 130 and be connected to the third switching element T3.

In an embodiment, widths or areas of the first pixel electrode PE1, the second pixel electrode PE2, and the third pixel electrode PE3 may be the same as each other. However, the disclosure is not limited thereto, and the widths or areas of the first pixel electrode PE1, the second pixel electrode PE2, and the third pixel electrode PE3 may be different from each other. For example, the width of the third pixel electrode PE3 may be smaller than the width of the second pixel electrode PE2, and the width of the second pixel electrode PE2 may be smaller than the width of the first pixel electrode PE1 and greater than the width of the third pixel electrode PE3. By way of example, the area of the third pixel electrode PE3 may be smaller than the area of the second pixel electrode PE2, and the area of the second pixel electrode PE2 may be smaller than the area of the first pixel electrode PE1 and greater than the area of the third pixel electrode PE3.

The first pixel electrode PE1, the second pixel electrode PE2, and the third pixel electrode PE3 may be reflective electrodes. The first pixel electrode PE1, the second pixel electrode PE2, and the third pixel electrode PE3 may have a stacked film structure in which a material layer having a high work function made of indium tin oxide (ITO), indium zinc oxide (IZO), zinc oxide (ZnO), or indium oxide (In₂O₃) and a reflective material layer made of silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof are stacked. The material layer having the high work function may be disposed on a layer above the reflective material layer to be disposed close to a light emitting layer OL. The first pixel electrode PE1, the second pixel electrode PE2, and the third pixel electrode PE3 may have a multilayer structure of ITO/Mg, ITO/MgF, ITO/Ag, and ITO/Ag/ITO, but are not limited thereto.

A pixel defining film 150 may be positioned on the first pixel electrode PE1, the second pixel electrode PE2, and the third pixel electrode PE3. The pixel defining film 150 may include an opening exposing the first pixel electrode PE1, an opening exposing the second pixel electrode PE2, and an opening exposing the third pixel electrode PE3, and may define the first light emitting area LA1, the second light emitting area LA2, the third light emitting area LA3, and the non-light emitting area NLA. For example, an area of the first pixel electrode PE1 that is not covered and is exposed by the pixel defining film 150 may be the first light emitting area LA1. An area of the second pixel electrode PE2 that is not covered and is exposed by the pixel defining film 150 may be the second light emitting area LA2. An area of the third pixel electrode PE3 that is not covered and is exposed by the pixel defining film 150 may be the third light emitting area LA3. Other areas in which the pixel defining film 150 is positioned may be the non-light emitting area NLA.

The pixel defining film 150 may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB).

In an embodiment, the pixel defining film 150 may overlap a bank 180 of the wavelength conversion layer WCL, which will be described later. A light emitting layer OL may be disposed on the first pixel electrode PE1, the second pixel electrode PE2, and the third pixel electrode PE3. In an embodiment in which the display device 10 is an organic light emitting display device, the light emitting layer OL may include an organic layer including an organic material. The organic layer may include an organic light emitting layer, and may further include at least one of a hole injection layer, a hole transporting layer, an electron transporting layer, and an electron injection layer as an auxiliary layer assisting emission of light in some cases.

In an embodiment, the light emitting layer OL may have a tandem structure including a plurality of organic light emitting layers disposed to overlap each other in a thickness direction and a charge generating layer disposed between the organic light emitting layers. Each of the organic light emitting layers disposed to overlap each other may emit light of the same wavelength, but may also emit light of different wavelengths. For example, each of the organic light emitting layers disposed to overlap each other may include an organic light emitting layer that emits light in a green wavelength and an organic light emitting layer that emits light in a blue wavelength. In an embodiment, each of the organic light emitting layers disposed to overlap each other may also include an organic light emitting layer that emits light in a red wavelength, an organic light emitting layer that emits light in a green wavelength, and an organic light emitting layer that emits light in a blue wavelength.

In an embodiment, the light emitting layer OL may have a shape of a continuous film formed across the plurality of light emitting areas LA1, LA2, and LA3 and the non-light emitting area NLA. In this case, the wavelength of light emitted by the light emitting layer OL may be the same. For example, the light emitting layer OL may emit blue light, white wavelength light, or ultraviolet rays from the plurality of light emitting areas LA1, LA2, and LA3.

A common electrode CE may be positioned on the light emitting layer OL. The common electrode CE may be a cathode electrode of each of the light emitting elements ED1, ED2, and ED3. In an embodiment, the common electrode CE may be semi-transmissive or transmissive. In case that the common electrode CE is semi-transmissive, the common electrode CE may include Ag, Mg, Cu, Al, Pt, Pd, Au, Ni, Nd, Ir, Cr, Li, Ca, LiF/Ca, LiF/Al, Mo, Ti, or a compound or mixture thereof, for example, a mixture of Ag and Mg. In addition, in case that the common electrode CE has a thickness of several tens to several hundreds of angstroms, the common electrode CE may be semi-transmissive.

In case that the common electrode CE is transmissive, the common electrode CE may include a transparent conductive oxide (TCO). For example, the common electrode CE may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), or the like within the spirit and the scope of the disclosure.

The first pixel electrode PE1, the light emitting layer OL, and the common electrode CE may constitute the first light emitting element ED1, the second pixel electrode PE2, the light emitting layer OL, and the common electrode CE may constitute the second light emitting element ED2, and the third pixel electrode PE3, the light emitting layer OL, and the common electrode CE may constitute the third light emitting element ED3. Each of the first light emitting element ED1, the second light emitting element ED2, and the third light emitting element ED3 may emit source light, and the source light may be provided to the wavelength conversion layer WCL. The source light may be, for example, blue light, but is not limited thereto, and may be white light or ultraviolet light. The first light emitting element ED1, the second light emitting element ED2, and the third light emitting element ED3 may be organic light emitting diodes.

A thin film encapsulation layer TFEL may be positioned on the common electrode CE. The thin film encapsulation layer TFEL may be commonly disposed in the first light emitting area LA1, the second light emitting area LA2, the third light emitting area LA3, and the non-light emitting area NLA. In an embodiment, the thin film encapsulation layer TFEL may directly cover the common electrode CE.

In an embodiment, the thin film encapsulation layer TFEL may include a first encapsulation inorganic film 171, an encapsulation organic film 173, and a second encapsulation inorganic film 175 sequentially stacked on the common electrode CE.

Each of the first encapsulation inorganic film 171 and the second encapsulation inorganic film 175 may include one or more of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. The encapsulation organic film 173 may include an acrylic resin, a methacrylic resin, polyisoprene, a vinyl resin, an epoxy resin, a urethane resin, a cellulose resin, a perylene resin, and the like within the spirit and the scope of the disclosure.

However, a structure of the thin film encapsulation layer TFEL is not limited to the above-described example, and a stacked structure of the thin film encapsulation layer TFEL may be variously changed.

A wavelength conversion layer WCL may be disposed on the light emitting element layer EML including the thin film encapsulation layer TFEL.

The wavelength conversion layer WCL may include a bank 180, a first wavelength conversion pattern 230, a second wavelength conversion pattern 240, and a capping layer 300.

The bank 180 may be disposed on the thin film encapsulation layer TFEL. The bank 180 may partition the light emitting areas LA1, LA2, and LA3 and the non-light emitting area NLA. The bank 180 may be disposed to overlap the non-light emitting area NLA and may block transmission of light. By way of example, the bank 180 may be positioned between the first wavelength conversion pattern 230 and the second wavelength conversion pattern 240, and prevent color mixing between the light emitting areas adjacent to each other.

The bank 180 may include an organic light blocking material and may be formed through a coating and exposure process of the organic light blocking material, or an inkjet method. For example, the bank 180 may include an organic material and a dye or pigment having light blocking properties mixed with the organic material. The organic material may include an acrylic resin, a methacrylic resin, polyisoprene, a vinyl resin, an epoxy resin, a urethane resin, a cellulose resin, a perylene resin, and the like within the spirit and the scope of the disclosure. The dye or pigment may include carbon black, etc.

The first wavelength conversion pattern 230 and the second wavelength conversion pattern 240 may be disposed on the thin film encapsulation layer TFEL.

The first wavelength conversion pattern 230 may be positioned on the thin film encapsulation layer TFEL and may overlap the first light emitting area LA1. The first wavelength conversion pattern 230 may convert or shift a peak wavelength of incident light to light having another specific peak wavelength and emit the converted or shifted light. In an embodiment, the first wavelength conversion pattern 230 may convert the source light provided from the first light emitting element ED1 into red light having a peak wavelength in the range of about 610 nm to 650 nm, and emit the converted red light.

The first wavelength conversion pattern 230 may include a first base resin 231 and first wavelength shifters 235 dispersed in the first base resin 231, and may further include second scatterers 233 dispersed in the first base resin 231.

The first base resin 231 may be made of a material having high light transmittance. In an embodiment, the first base resin 231 may be made of an organic material. For example, the first base resin 231 may include an organic material such as an epoxy resin, an acrylic resin, a cardo resin, or an imide resin.

The first scatterer 233 may have a refractive index different from that of the first base resin 231, and may form an optical interface with the first base resin 231. For example, the first scatterers 233 may be light scattering particles. The first scatterer 233 is not particularly limited as long as it is a material capable of scattering at least a portion of transmitted light, but may be, for example, a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), or the like, and examples of a material of the organic particle may include an acrylic resin, a urethane resin, or the like within the spirit and the scope of the disclosure. The first scatterer 233 may scatter light in a random direction irrespective of an incident direction of the incident light without substantially converting a wavelength of light transmitted through the first wavelength conversion pattern 230.

The first wavelength shifter 235 may convert or shift the peak wavelength of the incident light into another specific peak wavelength. In an embodiment, the first wavelength shifter 235 may convert the source light, for example, blue light, provided from the first light emitting element ED1 into red light having a single peak wavelength in the range of about 610 nm to about 650 nm and emit the red light.

Examples of the first wavelength shifter 235 may include, for example, a quantum dot, a quantum bar, or a phosphor. For example, the quantum dot may be a particulate material that emits a specific color as electrons transition from a conduction band to a valence band.

The quantum dot may be a semiconductor nano-crystal material. The quantum dot may have a specific bandgap according to its composition and size to absorb light and emit light having a unique wavelength. Examples of the semiconductor nano-crystal of the quantum dot may include group IV nano-crystal, group II-VI compound nano-crystal, group III-V compound nano-crystal, group IV-VI nano-crystal, or a combination thereof.

The group II-VI compound may be selected from the group consisting of a binary compound selected from the group consisting of CdSe, CdTe, ZnS, ZnSe, ZnTe, ZnO, HgS, HgSe, HgTe, MgSe, MgS, and mixtures thereof; a ternary compound selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures of thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group III-V compound may be selected from the group consisting of a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The group IV-VI compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. A group IV element may be selected from the group consisting of Si, Ge, and mixtures thereof. A group IV compound may be a binary compound selected from the group consisting of SiC, SiGe, and mixtures thereof.

In this case, the binary compound, the ternary compound, or the quaternary compound may be present in a particle at a uniform concentration or may be present in the same particle in a state of partially different concentration distributions. The quantum dot may have a core/shell structure in which one quantum dot surrounds another quantum dot. An interface between the core and the shell may have a concentration gradient in which a concentration of the element present in the shell decreases toward the center.

According to an embodiment, the quantum dot may have a core-shell structure including a core including the above-described nano-crystal and a shell surrounding the core. The shell of the quantum dot may serve as a protective layer for maintaining semiconductor properties by preventing chemical modification of the core and/or a charging layer for imparting electrophoretic properties to the quantum dot. The shell may be a single layer or multiple layers. Examples of the shell of the quantum dot may include a metal or non-metal oxide, a semiconductor compound, or a combination thereof.

For example, examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO or a ternary compound such as MgAl₂O₄, CoFe₂O₄, NiFe₂O₄, or CoMn₂O₄, but the disclosure is not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but the disclosure is not limited thereto.

The light emitted by the first wavelength shifter 235 may have an emission wavelength spectrum full width of half maximum (FWHM) of about 45 nm or less, or about 40 nm or less, or about 30 nm or less, and through this, color purity and color reproducibility of colors displayed by the display device 10 may be further improved. The light emitted by the first wavelength shifter 235 may be emitted toward several directions regardless of the incident direction of the incident light. Through this, side visibility of the first color displayed in the first light emitting area LA1 may be improved.

A portion of the source light provided from the first light emitting element ED1 may not be converted into the red light by the first wavelength shifter 235. However, light that is not converted to the red light among the source light may be blocked by the color filter layer CFL disposed on an upper portion. On the other hand, the red light converted by the first wavelength conversion pattern 230 among the source light is transmitted through the color filter layer CFL and is emitted to the outside.

The second wavelength conversion pattern 240 may be positioned on the thin film encapsulation layer TFEL and may overlap the second light emitting area LA2. The second wavelength conversion pattern 240 may convert or shift a peak wavelength of the incident light to light having another specific peak wavelength and emit the converted or shifted light. In an embodiment, the second wavelength conversion pattern 240 may convert the source light provided from the second light emitting element ED2 into green light in the range of about 510 nm to 550 nm, and emit the converted green light.

The second wavelength conversion pattern 240 may include a second base resin 241 and second wavelength shifters 245 dispersed in the second base resin 241, and may further include second scatterers 243 dispersed in the second base resin 241.

The second base resin 241 may be made of a material having high light transmittance. In an embodiment, the second base resin 241 may be made of an organic material. The second base resin 241 may be made of the same material as the first base resin 231, or may include at least one of the materials described as the constituent materials of the first base resin 231.

The second wavelength shifter 245 may convert or shift the peak wavelength of the incident light into another specific peak wavelength. In an embodiment, the second wavelength shifter 245 may convert the source light, for example, blue light, having a peak wavelength in the range of about 440 nm to about 480 nm, into green light having a peak wavelength in the range of about 510 nm to about 550 nm.

The second wavelength shifter 245 may be, for example, a quantum dot, a quantum bar, or a phosphor. A more detailed description of the second wavelength shifter 245 is substantially the same as or similar to that of the first wavelength shifter 235 described above and thus will be omitted. In an embodiment, both the first wavelength shifter 235 and the second wavelength shifter 245 may be formed of quantum dots. In this case, a particle size of the quantum dots constituting the first wavelength shifter 235 may be greater than a particle size of the quantum dots constituting the second wavelength shifter 245.

The second scatterer 243 may have a refractive index different from that of the second base resin 241, and may form an optical interface with the second base resin 241. For example, the second scatterers 243 may be light scattering particles. Other detailed descriptions of the second scatterers 243 are substantially the same as or similar to those of the first scatterers 233 and thus will be omitted.

The source light emitted from the second light emitting element ED2 may be provided to the second wavelength conversion pattern 240, and the second wavelength shifter 245 may convert the source light provided from the second light emitting element ED2 into green light having a peak wavelength in the range of about 510 nm to about 550 nm and emit the green light.

A portion of the source light may transmit through the second wavelength conversion pattern 240 without being converted into the green light by the second wavelength shifter 245. However, the light that is not converted into the green light may be blocked by the color filter layer CFL. On the other hand, the green light converted by the second wavelength conversion pattern 240 among the source light may be transmitted through the color filter layer CFL and may be emitted to the outside.

The capping layer 300 may be disposed on the bank 180, the first wavelength conversion pattern 230, and the second wavelength conversion pattern 240 to cover the bank 180, the first wavelength conversion pattern 230, and the second wavelength conversion pattern 240. Accordingly, the capping layer 300 may prevent impurities such as moisture or air from permeating from the outside and damaging or contaminating the bank 180, the first wavelength conversion pattern 230, and the second wavelength conversion pattern 240.

The capping layer 300 may be made of an inorganic material. For example, the capping layer 300 may include silicon nitride, aluminum nitride, zirconium nitride, titanium nitride, hafnium nitride, tantalum nitride, silicon oxide, aluminum oxide, titanium oxide, tin oxide, and silicon oxynitride.

In an embodiment, the capping layer 300 may be disposed adjacent to the substrate SUB in an area overlapping the third light emitting area LA3. For example, the capping layer 300 may be disposed closer to the substrate SUB in the third light emitting area LA3 than in the first light emitting area LA1 and the second light emitting area LA2. In an embodiment, a distance from the substrate SUB to the capping layer 300 may be shorter in the third light emitting area LA3 than in the first and second light emitting areas LA1 and LA2.

The filling layer FIL may be disposed on the capping layer 300. The filling layer FIL may be disposed directly on the capping layer 300 and may be disposed between the wavelength conversion layer WCL and the color filter layer CFL. The filling layer FIL may be in contact with the wavelength conversion layer WCL and the color filter layer CFL, respectively. The filling layer FIL may entirely cover an upper portion of the wavelength conversion layer WCL. The filling layer FIL may be entirely disposed in the display area (“DPA” in FIG. 1) of the display device 10. For example, the filling layer FIL may be disposed on the light emitting areas LA1, LA2, and LA3 and the non-light emitting area NLA in the display area. The filling layer FIL may be extended and disposed in the non-display area (“NDA” in FIG. 1) of the display device 10.

In the third light emitting area LA3, the source light emitted from the third light emitting element ED3 is transmitted to the color filter layer CFL without light conversion. However, for characteristics such as positive side luminance ratio, a pattern including scattering particles that may scatter light is required. However, a patterning process for forming the pattern involves a mask process and inevitably causes significant material loss. Therefore, in an embodiment, an additional patterning process may be omitted in an area corresponding to the third light emitting area LA3 and instead, the filling layer FIL including filling particles FP that scatter light may be formed throughout the display area DPA.

The filling layer FIL may include a filling resin FR and filling particles FP dispersed in the filling resin FR. The filling resin FR may be made of a material with high light transmittance. For example, the filling resin FR may include a silicon resin, an acrylic resin, an epoxy resin, polyacrylate, polyurethane, polyethylene, or ester resin.

The filling particles FP may be light scattering particles that scatter light. The filling particles FP may include, for example, any one or more selected from the group consisting of silica (SiO₂), alumina, silicon, titanium oxide (TiO₂), zirconia oxide (ZrO₂), barium sulfate, zinc oxide (ZnO), and polymethyl methacrylate (PMMA). In an embodiment, the filling particle FP may be titanium oxide.

The filling layer FIL may be formed by applying a composition obtained by mixing the filling particles FP, a dispersant, a thermal initiator, and a photoinitiator with a solvent on the filling resin FR. The content of filling particles FP may be in a range of about 1 to about 10 wt % with respect to the total composition. If the content of the filling particles FP is about 1 wt % or more with respect to the total composition, the positive side luminance ratio may be increased by scattering the light transmitting through the wavelength conversion layer WCL. If the content of filling particles FP is about 10 wt % or less with respect to the total composition, coating properties of the composition may be facilitated and light efficiency may be prevented from being reduced.

A thickness of the filling layer FIL may be in a range of about 0.1 to about 10 μm. If the thickness of the filling layer FIL is about 0.1 μm or more, flatness of the filling layer FIL may be secured and a gap with the color filter layer CFL may be readily formed. If the thickness of the filling layer FIL is about 10 μm or less, it is possible to prevent defects from occurring due to moisture or oxygen permeating from the outside through the filling layer FIL.

A refractive index of the filling resin FR of the filling layer FIL may be in a range of about 1.4 to about 1.7. If the refractive index of the filling resin FR of the filling layer FIL is 1.4 or more, a difference in refractive index between adjacent layers may increase, thereby preventing a decrease in light efficiency. If the refractive index of the filling resin FR of the filling layer FIL is about 1.7 or less, a viscosity of the composition of the filling layer FIL may increase, thereby preventing a decrease in applicability.

According to an embodiment, the thickness of the filling layer FIL may be different for each area. A thickness TT1 of the filling layer FIL in the third light emitting area LA3 may be greater than a thickness TT2 of the filling layer FIL in the first light emitting area LA1 or the second light emitting area LA2. Here, the thickness of the filling layer FIL may be a distance between the capping layer 300 and the color filter layer CFL in the corresponding area. If the thickness TT1 of the filling layer FIL in the third light emitting area LA3 is greater than that in other light emitting areas LA2 and LA3, the positive side luminance ratio may be increased by scattering the light emitted from the third light emitting area LA3. In the first light emitting area LA1 and the second light emitting area LA2, since sufficient light scattering occurs from the scatterers of the first wavelength conversion pattern 230 and the second wavelength conversion pattern 240, it is preferable in terms of efficiency that the thickness of the filling layer FIL is small.

As described above, by forming the filling layer FIL including the filling particles FP that scatter light between the wavelength conversion layer WCL and the color filter layer CFL, a pattern with a separate light scattering function may be omitted in the third light emitting area LA3. Accordingly, manufacturing costs according to a mask process may be reduced and a process may be simplified. As the filling layer FIL is disposed throughout the display area DPA, a light scattering effect may be applied to the third light emitting area LA3 in which light is emitted without light conversion in the wavelength conversion layer WCL, thereby increasing the positive side luminance ratio.

The color filter layer CFL may be disposed on the wavelength conversion layer WCL, and the counter substrate TSUB may be disposed on the color filter layer CFL.

The color filter layer CFL may include a first color filter 360, a second color filter 370, and a third color filter 380. The color filter layer CFL may include a first color pattern 365, a second color pattern 375, and a third color pattern 385.

The first color filter 360 may be disposed between the counter substrate TSUB and the filling layer FIL, and may be disposed to overlap the third light emitting area LA3. The first color filter 360 may be in direct contact with the filling layer FIL. The first color pattern 365 may be disposed to be spaced apart from the first color filter 360 and overlap the non-light emitting area NLA.

The first color filter 360 and the first color pattern 365 may selectively transmit the light of the third color (for example, the blue light) and block or absorb the light of the first color (for example, the red light) and the light of the second color (for example, the green light). In an embodiment, the first color filter 360 may be a blue color filter, and may include a blue colorant such as a blue dye or a blue pigment. Herein, a colorant is a concept including both a dye and a pigment.

The second color filter 370 may be disposed between the counter substrate TSUB and the filling layer FIL, and may be disposed to overlap the first light emitting area LA1. The second color filter 370 may overlap the first light emitting element ED1 and the first wavelength conversion pattern 230. In an embodiment, one side or a side of the second color filter 370 may overlap the non-light emitting area NLA and may overlap the first color filter 360 adjacent thereto. The other side of the second color filter 370 may overlap the non-light emitting area NLA and may overlap the first color pattern 365. The second color pattern 375 may be disposed to be spaced apart from the second color filter 370 and overlap the non-light emitting area NLA. The second color pattern 375 may be disposed to overlap the first color filter 360 in the non-light emitting area NLA. The second color filter 370 may be in direct contact with the filling layer FIL.

The second color filter 370 and the second color pattern 375 may selectively transmit light of a first color (for example, red light) and block or absorb light of a second color (for example, green light) and light of a third color (for example, blue light). For example, the second color filter 370 may be a red color filter and may include a red colorant such as red dye or red pigment.

The third color filter 380 may be disposed between the counter substrate TSUB and the filling layer FIL and may overlap the second light emitting area LA2. The third color filter 380 may overlap the second light emitting element ED2 and the second wavelength conversion pattern 240. In an embodiment, one side or a side of the third color filter 380 may overlap the non-light emitting area NLA and may overlap the first color filter 360 and the first color pattern 365 adjacent thereto. The other side of the third color filter 380 may overlap the non-light emitting area NLA and may overlap the first color filter 360 and the second color pattern 375 adjacent thereto. The third color pattern 385 may be disposed to be spaced apart from the third color filter 380 and overlap the non-light emitting area NLA. The third color pattern 385 may be disposed to overlap the first color filter 360 and the second color filter 370 in the non-light emitting area NLA. The third color filter 380 and the third color pattern 385 may be in direct contact with the filling layer FIL.

The third color filter 380 may selectively transmit the light of the second color (for example, the green light) and block or absorb the light of the first color (for example, the red light) and the light of the third color (for example, the blue light). For example, the third color filter 380 may be a green color filter and may include a green colorant such as green dye or green pigment.

As described above, in the non-light emitting area NLA, the first to third color filters 360, 370, and 380 and the first to third color patterns 365, 375, and 385 may overlap to block or absorb the light. For example, the first color pattern 365, the second color filter 370, and the third color filter 380 may overlap in the non-light emitting area NLA disposed on one side or a side of the second light emitting area LA2, and the first color filter 360, the second color pattern 375, and the third color filter 380 may overlap in the non-light emitting area NLA disposed on the other side of the second light emitting area LA2.

As described above, in the display device according to an embodiment, a pattern with a separate light scattering function may be omitted in the third light emitting area LA3 by forming the filling layer FIL including the filling particles FP that scatter light between the wavelength conversion layer WCL and the color filter layer CFL. Accordingly, manufacturing costs according to a mask process may be reduced and a process may be simplified. As the filling layer FIL is disposed throughout the display area DPA, a light scattering effect may be applied to the third light emitting area LA3 in which light is emitted without light conversion in the wavelength conversion layer WCL, thereby increasing the positive side luminance ratio.

Hereinafter, a method for manufacturing the display device 10 according to an embodiment illustrated in FIG. 5 described above will be described.

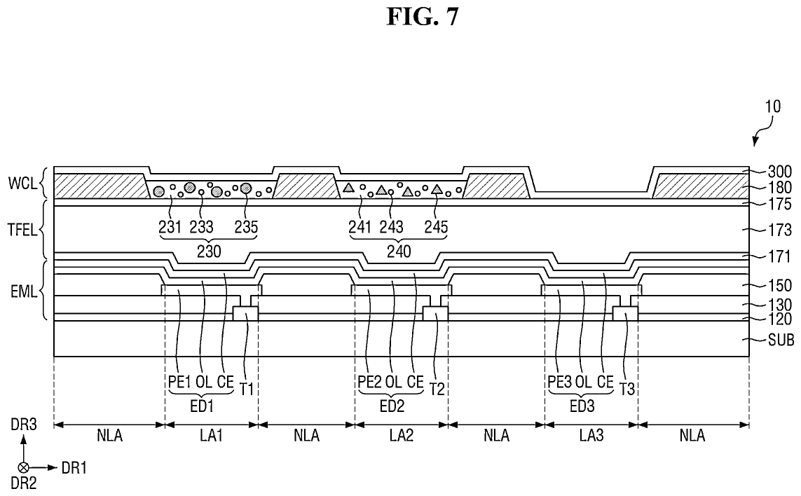

FIGS. 7 to 9 are schematic cross-sectional views illustrating a method for manufacturing a display device according to an embodiment for each process.

Referring to FIG. 7, a plurality of switching elements T1, T2, and T3, a plurality of light emitting elements ED1, ED2, and ED3, first and second insulating layers 120 and 130, and a pixel defining film 150 are formed on a substrate SUB to form a light emitting element layer EML. A first encapsulation inorganic film 171, an encapsulation organic film 173, and a second encapsulation inorganic film 175 are formed on the light emitting element layer EML to form a thin film encapsulation layer TFEL.

The light emitting element layer EML and the thin film encapsulation layer TFEL disposed on the substrate SUB may be formed by depositing a material forming each layer, such as a metal material, and patterning the material using a mask. The first and second insulating layers 120 and 130 and the pixel defining film 150 may be formed by applying a material forming each layer, such as an insulating material, or, through a patterning process using a mask. A description of the structure of the plurality of layers disposed on the substrate SUB is the same as that described above, and thus a detailed description thereof will be omitted.

A bank 180 is patterned on the thin film encapsulation layer TFEL. Between the banks 180, a first wavelength conversion pattern 230 is formed in a first light emitting area LA1, and a second wavelength conversion pattern 240 is formed in a second light emitting area LA2. The first wavelength conversion pattern 230 and the second wavelength conversion pattern 240 may be formed using an inkjet printing method. A wavelength conversion layer WCL is formed by stacking a capping layer 300 on the bank 180, the first wavelength conversion pattern 230, the second wavelength conversion pattern 240, and the thin film encapsulation layer TFEL. The capping layer 300 may be formed to be in direct contact with the second encapsulation inorganic film 175 of the thin film encapsulation layer TFEL in the third light emitting area LA3.

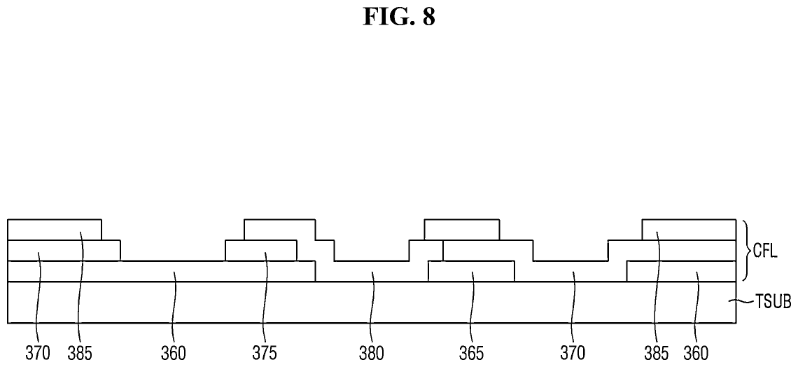

Referring to FIG. 8, a first color filter 360 and a first color pattern 365 are formed by applying and patterning a first color filter material on a counter substrate TSUB. A second color filter 370 and a second color pattern 375 are formed by applying and patterning a second color filter material on the counter substrate TSUB. A third color filter 380 and a third color pattern 385 are formed by applying and patterning a third color filter material on the counter substrate TSUB to form a color filter layer CFL.

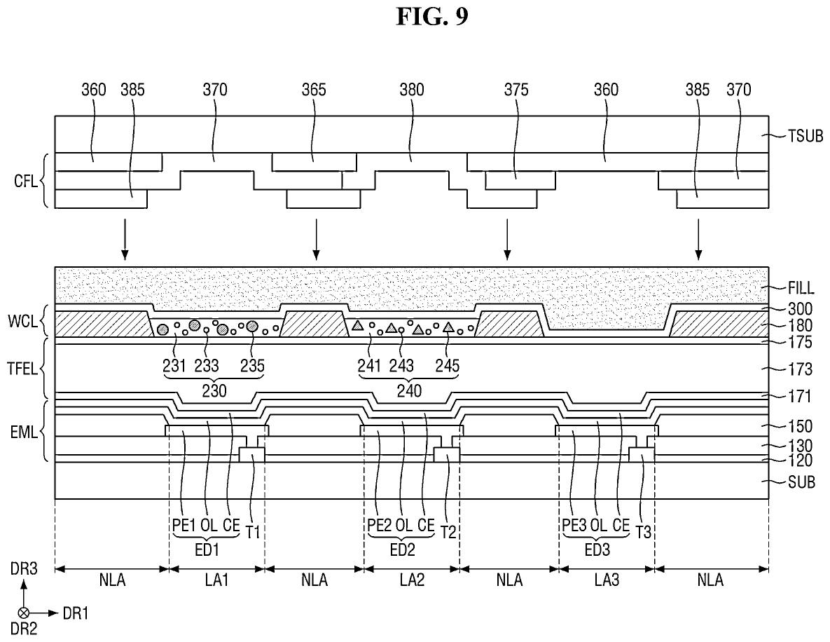

Referring to FIG. 9, a filling material layer FILL is formed by applying a filling material on the substrate SUB on which the wavelength conversion layer WCL is formed. The filling material layer FILL may be formed using a composition including a filling resin and filling particles dispersed in the filling resin. The filling material layer FILL may be formed using a solution process, for example, spin coating, slit coating, inkjet printing, etc. In an embodiment, the filling material layer FILL is formed on the substrate SUB, the disclosure is not limited thereto and the filling material layer FILL may also be formed on the counter substrate TSUB.

The counter substrate TSUB is aligned on the substrate SUB. In this case, the counter substrate TSUB is aligned so that the color filter layer CFL faces the substrate SUB. The counter substrate TSUB and the substrate SUB are bonded to each other by pressing the counter substrate TSUB and the substrate SUB. In case that the counter substrate TSUB and the substrate SUB are bonded, the first color filter 360 corresponds to the third light emitting area LA3, the second color filter 370 corresponds to the first light emitting area LA1, and the third color filter 380 corresponds to the second light emitting area LA2.

The filling material layer FILL is cured by irradiating UV light or applying heat depending on the material of the filling material layer FILL to form a filling layer FIL. Therefore, a display device 10 in which the filling layer FIL is disposed between the substrate SUB and the counter substrate TSUB may be manufactured.

In the method for manufacturing the display device according to an embodiment, a mask process for forming a pattern with a separate light scattering function may be omitted in the third light emitting area LA3 by forming the filling layer FIL including the filling particles that scatter light between the wavelength conversion layer WCL and the color filter layer CFL.

Hereinafter, a display device 10 according to an embodiment will be described with reference to other drawings.

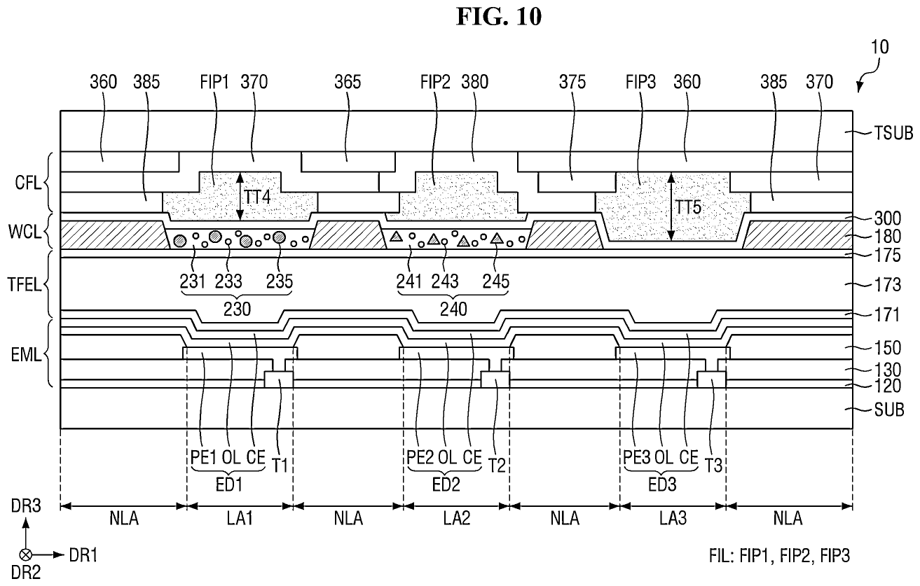

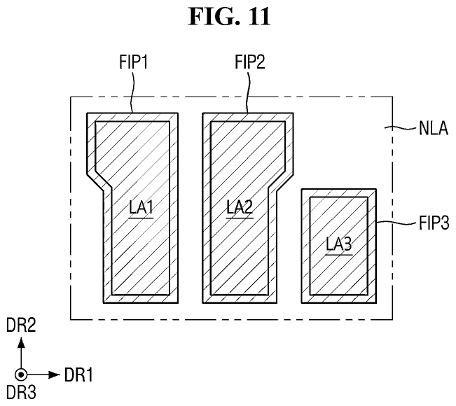

FIG. 10 is a schematic cross-sectional view illustrating a display device according to an embodiment. FIG. 11 is a schematic plan view illustrating each light emitting area and a non-light emitting area of the display device according to an embodiment.

Referring to FIGS. 10 and 11, the embodiment may be different from the embodiment of FIGS. 5 and 6 described above in that the wavelength conversion layer WCL and the color filter layer CFL are in contact with each other. Hereinafter, descriptions overlapping the above-described embodiment will be omitted and differences from the above-described embodiment will be described.

The display device 10 may include a substrate SUB, a light emitting element layer EML, a thin film encapsulation layer TFEL, a wavelength conversion layer WCL, a filling layer FIL, a color filter layer CFL, and a counter substrate TSUB.

The wavelength conversion layer WCL and the color filter layer CFL may be in contact with each other in the non-light emitting area NLA. By way of example, the capping layer 300 of the wavelength conversion layer WCL may be in contact with the third color filter 380 and the third color pattern 385 of the color filter layer CFL.

The capping layer 300 and the third color pattern 385 may be in contact with each other in the non-light emitting area NLA disposed on one side or a side of the first light emitting area LA1 (for example, the other side of the third light emitting area LA3), and the capping layer 300 and the third color filter 380 may be in contact with each other in the non-light emitting area NLA (for example, one side or a side of the second light emitting area LA2) disposed on the other side of the first light emitting area LA1. The capping layer 300 and the third color filter 380 may be in contact with each other the non-light emitting area NLA disposed on the other side of the second light emitting area LA2 (for example, one side or a side of the third light emitting area LA3).

In case that the wavelength conversion layer WCL and the color filter layer CFL are in contact with each other, a distance (optical distance) through which light emitted from the wavelength conversion layer WCL reaches the color filter layer CFL may be reduced. Therefore, light efficiency may be improved as the optical distance decreases.

The filling layer FIL may be disposed between the wavelength conversion layer WCL and the color filter layer CFL. Unlike the embodiment of FIGS. 5 and 6 described above, the filling layer FIL may be disposed in an island shape.

The filling layer FIL may include a first filling pattern FIP1, a second filling pattern FIP2, and a third filling pattern FIP3 spaced apart from each other.

The first filling pattern FIP1 may be disposed to overlap the first light emitting area LA1 and may be disposed to overlap the first wavelength conversion pattern 230 of the wavelength conversion layer WCL. The first filling pattern FIP1 may be disposed between the capping layer 300 and the second color filter 370. The second filling pattern FIP2 may be disposed to overlap the second light emitting area LA2 and may be disposed to overlap the second wavelength conversion pattern 240 of the wavelength conversion layer WCL. The second filling pattern FIP2 may be disposed between the capping layer 300 and the third color filter 380. The third filling pattern FIP3 may be disposed to overlap the third light emitting area LA3. The third filling pattern FIP3 may be disposed between the capping layer 300 and the first color filter 360.

The first filling pattern FIP1, the second filling pattern FIP2, and the third filling pattern FIP3 may have at least some areas that are different or the same. For example, the area of the first filling pattern FIP1 and the area of the second filling pattern FIP2 may be the same, and the area of the third filling pattern FIP3 may be smaller than the area of the first filling pattern FIP1 or the area of the second filling pattern FIP2. However, the disclosure is not limited thereto, and the first filling pattern FIP1, the second filling pattern FIP2, and the third filling pattern FIP3 may also have the same area as each other.

A thickness TT4 of the first filling pattern FIP1 or the second filling pattern FIP2 may be smaller than a thickness TT5 of the third filling pattern FIP3. For example, the thickness TT5 of the third filling pattern FIP3 may be greater than the thickness TT4 of the first filling pattern FIP1 or the second filling pattern FIP2. In case that the thickness TT5 of the third filling pattern FIP3 is greater than the thickness TT4 of the first filling pattern FIP1 or the second filling pattern FIP2, a positive side luminance ratio may be increased by scattering the light emitted from the third light emitting area LA3. In the first light emitting area LA1 and the second light emitting area LA2, since sufficient light scattering occurs from the scatterers of the first wavelength conversion pattern 230 and the second wavelength conversion pattern 240, it is preferable in terms of efficiency that the thickness TT4 of the first filling pattern FIP1 and the second filling pattern FIP2 is small.

As described above, the display device 10 according to an embodiment may improve light efficiency by reducing the optical distance by bringing the wavelength conversion layer WCL into contact with the color filter layer CFL.

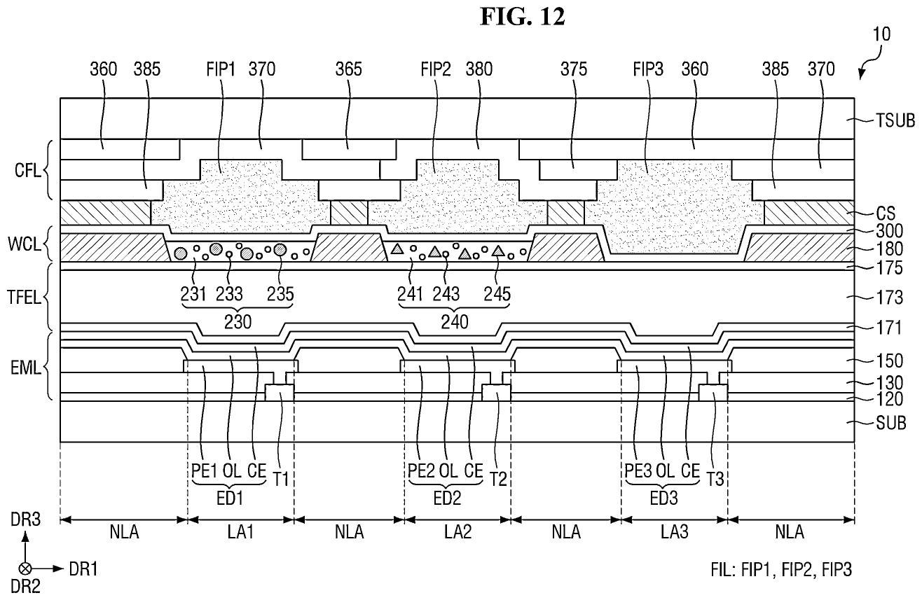

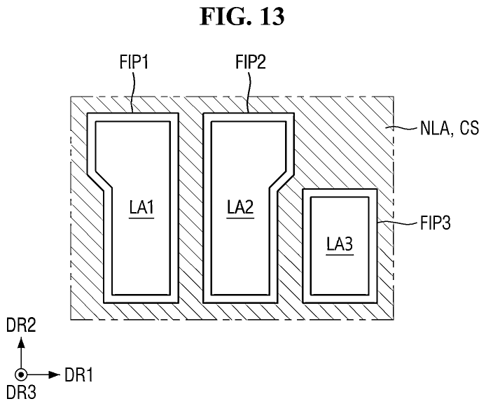

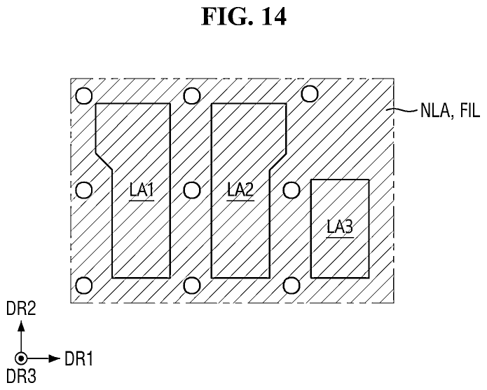

FIG. 12 is a schematic cross-sectional view illustrating a display device according to an embodiment. FIG. 13 is a schematic plan view illustrating an example of a spacer of the display device according to an embodiment. FIG. 14 is a schematic plan view illustrating another example of the spacer of the display device according to an embodiment.

Referring to FIGS. 12 and 13, the embodiment may be different from the embodiments of FIGS. 5 to 11 described above in that a spacer CS is further disposed between the wavelength conversion layer WCL and the color filter layer CFL.

The display device 10 may include a substrate SUB, a light emitting element layer EML, a thin film encapsulation layer TFEL, a wavelength conversion layer WCL, a filling layer FIL, a spacer CS, a color filter layer CFL, and a counter substrate TSUB.

The spacer CS may be disposed between the wavelength conversion layer WCL and the color filter layer CFL. The spacer CS may be directly disposed on the capping layer 300 of the wavelength conversion layer WCL and may be in direct contact with the color filter layer CFL. The spacer CS may maintain a gap between the substrate SUB and the counter substrate TSUB. For example, the spacer CS may maintain a gap between the capping layer 300 and the third color filter 380 and between the capping layer 300 and the third color pattern 385.

The spacer CS may be disposed to non-overlap the first light emitting area LA1, the second light emitting area LA2, and the third light emitting area LA3. The spacer CS may be disposed to overlap the non-light emitting area NLA and may be disposed to overlap the bank 180 of the wavelength conversion layer WCL.

A thickness of the spacer CS may be in a range of about 0.1 to about 4.5 μm. In case that the thickness of the spacer CS is about 0.1 μm or more, the spacer CS may prevent structures from being damaged during the bonding process by maintaining the gap between the substrate SUB and the counter substrate TSUB. In case that the thickness of the spacer CS is about 4.5 μm or less, the spacer may prevent the gap of the display device 10 from increasing, thereby implementing a thin display device 10.

A cross-sectional shape of the spacer CS may be symmetrical. For example, the cross-sectional shape of the spacer CS may be a regular trapezoid, an inverted trapezoid, or a rectangle. However, the disclosure is not limited thereto, and the cross-sectional shape of the spacer CS may also be asymmetrical.

In an embodiment, the spacer CS may be disposed in the non-light emitting area NLA and may have a mesh shape in plan view. In this case, the filling layer FIL may be disposed in an island shape, as illustrated in FIGS. 10 and 11 described above. Since the structure of the filling layer FIL is described in detail with reference to FIGS. 10 and 11, a detailed description thereof will be omitted.

Referring to FIG. 14, in an embodiment, the spacer CS may be disposed in the non-light emitting area NLA and may be formed in a dot shape in plan view. At least one or more spacers CS may be disposed between the light emitting areas LA1, LA2, and LA3, and may be disposed to be spaced apart from each other at equal intervals. However, the disclosure is not limited thereto, and the spacers CS may also be disposed to be spaced apart from each other at different intervals.

In this case, the filling layer FIL may be entirely disposed in the display area excluding the spacers CS. For example, the filling layer FIL may be disposed to overlap each of the light emitting areas LA1, LA2, and LA3 and the non-light emitting area NLA.

As described above, the display device 10 according to an embodiment may prevent the structures from being damaged during the bonding process by disposing the spacer CS between the wavelength conversion layer WCL and the color filter layer CFL to maintain the gap between the substrate SUB and the counter substrate TSUB.

Hereinafter, simulation and experimental examples of the above-described display device 10 will be described.

### Simulation

The display device 10 including the filling layer FIL illustrated in FIG. 5 was constructed, and the front side luminance ratio, light efficiency ratio, and white efficiency ratio of the third light emitting area LA3 were simulated according to the thickness of the filling layer FIL in the third light emitting area LA3 and the content of filling particles in the filling layer FIL. The filling particles in the filling layer FIL were composed of titanium oxide particles. The results of such simulation are shown in Table 1 below. In Table 1 below, the content of filling particles represents the content of filling particles for the entire filling layer composition.

TABLE 1

| Content of | | | | |
|---|---|---|---|---|
| Filling | Thickness | Front Side | Blue Light | White Light |
| Particles | of Filling | Luminance | Efficiency | Efficiency |
| (wt %) | Layer (μm) | Ratio | Ratio | Ratio |
| 6.5 | 7 | 69.30 | 111.40 | 105.00 |
| | 5 | 69.80 | 116.10 | 109.50 |
| | 3 | 70.20 | 120.20 | 113.20 |
| 5.5 | 7 | 67.50 | 120.50 | 106.20 |
| | 5 | 68.20 | 125.30 | 110.60 |
| | 3 | 68.10 | 129.40 | 114.30 |
| 5 | 7 | 66.50 | 126.20 | 106.80 |
| | 5 | 66.70 | 130.90 | 111.30 |
| | 3 | 67.40 | 135.00 | 115.00 |
| 4.5 | 7 | 65.70 | 132.60 | 107.50 |
| | 5 | 66.20 | 137.30 | 111.90 |
| | 3 | 66.20 | 141.40 | 115.60 |
| 4 | 7 | 63.70 | 140.40 | 108.20 |
| | 5 | 63.80 | 145.00 | 112.70 |
| | 3 | 64.20 | 149.00 | 116.40 |

Referring to Table 1, as the content of filling particles in the filling layer increases, the front side luminance ratio of the third light emitting area that emits a blue color increases, but a light efficiency ratio of blue and white colors was decreased. As the thickness of the filling layer in the third light emitting area was decreased, the front side luminance ratio of a blue color was entirely increased, and the light efficiency ratio of the blue and white colors was also increased.

Through such a result, considering the front side luminance ratio of the blue color and the light efficiency ratio of the blue and white colors, the content of filling particles in the filling layer may be adjusted to meet the specifications required by the product.

### EXPERIMENTAL EXAMPLES

### Example

The display device 10 including the filling layer FIL illustrated in FIG. 5 was constructed, the filling particles in the filling layer FIL are composed of titanium oxide particles, and the content of titanium oxide particles was set to 6.5 wt %.

### Comparative Example

Instead of the filling layer in the example, a transparent pattern including titanium oxide particles was formed only in the third light emitting area LA3. The content of titanium oxide particles was set to 6.2 wt %.

In the display devices according to the above-described example and comparative example, the light efficiency of the third light emitting area LA3 was measured according to a thickness of the filling layer and a thickness of the transparent pattern. The results of such measurement are shown in Table 2 below.

TABLE 2

| | Thickness (μm) | Efficiency (cd/A) |
|---|---|---|
| Example | 9.8 | 4.7 |
| | 6.27 | 5.29 |
| | 6 | 5.37 |
| Comparative Example | 7.05 | 4.86 |
| | 7.61 | 4.67 |
| | 8.76 | 4.44 |

Referring to Table 2, the efficiency of the third light emitting area of the display device according to the example was increased as the thickness of the filling layer is decreased. The efficiency of the third light emitting area of the display device according to the comparative example was increased as the thickness of the transparent pattern is decreased. It was confirmed that the efficiency of the third light emitting area was further increased in the example compared to the comparative example.

Through such a result, it may be seen that the display device of the example using the filling layer has better blue efficiency than the display device of the comparative example using the transparent pattern.

In concluding the detailed description, those skilled in the art will appreciate that many variations and modifications can be made to the disclosed embodiments without substantially departing from the principles of the disclosure. Therefore, the disclosed embodiments are used in a generic and descriptive sense only and not for purposes of limitation.

What is claimed is:

1. A display device comprising:
light emitting areas and a non-light emitting area;
a substrate;
a light emitting element layer disposed on the substrate;
a thin film encapsulation layer disposed on the light emitting element layer;
a wavelength conversion layer disposed on the thin film encapsulation layer;
a counter substrate facing the substrate;
a color filter layer disposed on a surface of the counter substrate; and
a filling layer filled between the color filter layer and the wavelength conversion layer, the filling layer including filling particles.

2. The display device of claim 1, wherein
the light emitting areas include a first light emitting area, a second light emitting area, and a third light emitting area, and
the wavelength conversion layer includes a first wavelength conversion pattern overlapping the first light emitting area and a second wavelength conversion pattern overlapping the second light emitting area.

3. The display device of claim 2, wherein
the wavelength conversion layer includes a capping layer covering the first wavelength conversion pattern, the second wavelength conversion pattern, and the thin film encapsulation layer, and
the capping layer is disposed closer to the substrate in the third light emitting area than the first light emitting area and the second light emitting area.

4. The display device of claim 1, wherein
the filling layer includes a filling resin including the filling particles, and
a content of the filling particles is in a range of about 1 wt % to about 10 wt %.

5. The display device of claim 1, wherein the filling particles include light scattering particles.

6. The display device of claim 5, wherein the filling particles are at least one selected from the group consisting of silica (SiO₂), alumina, silicon, titanium oxide (TiO₂), zirconia oxide (ZrO₂), barium sulfate, zinc oxide (ZnO), and polymethyl methacrylate (PMMA).

7. The display device of claim 1, wherein a thickness of the filling layer is in a range of about 0.1 μm to about 10 μm.

8. The display device of claim 4, wherein a refractive index of the filling resin of the filling layer is in a range of about 1.4 to about 1.7.

9. The display device of claim 1, wherein a thickness of the filling layer measured in a vertical direction in one of the light emitting areas is different from a thickness of the filling layer measured in the vertical direction in the other one of the light emitting areas.

10. The display device of claim 2, wherein a thickness of the filling layer measured in a vertical direction in the third light emitting area is greater than a thickness of the filling layer measured in the vertical direction in the first light emitting area or the second light emitting area.

11. The display device of claim 1, further comprising:
a spacer disposed between the wavelength conversion layer and the color filter layer.

12. The display device of claim 11, wherein the spacer overlaps the non-light emitting area and does not overlap the light emitting area.

13. The display device of claim 11, wherein a thickness of the spacer is in a range of about 0.1 μm to about 4.5 μm.

14. The display device of claim 11, wherein a planar shape of the spacer is a substantially mesh shape or a dot shape.

15. A display device comprising:
light emitting areas and a non-light emitting area;
a substrate;
a light emitting element layer disposed on the substrate;
a thin film encapsulation layer disposed on the light emitting element layer;
a wavelength conversion layer disposed on the thin film encapsulation layer;
a counter substrate facing the substrate;
a color filter layer disposed on a surface of the counter substrate; and
a filling layer filled between the color filter layer and the wavelength conversion layer and including filling particles,
wherein the color filter layer and the wavelength conversion layer contact each other.

16. The display device of claim 15, wherein the filling layer includes a first filling pattern, a second filling pattern, and a third filling pattern that overlap the light emitting areas and are spaced apart from each other.

17. The display device of claim 16, wherein
the light emitting areas include a first light emitting area, a second light emitting area, and a third light emitting area, and
the first filling pattern overlaps the first light emitting area, the second filling pattern overlaps the second light emitting area, and the third filling pattern overlaps the third light emitting area.

18. The display device of claim 17, wherein a thickness of the third filling pattern is greater than a thickness of the first filling pattern or a thickness of the second filling pattern.

19. The display device of claim 15, wherein the filling particles include light scattering particles and are at least one selected from the group consisting of silica (SiO₂), alumina, silicon, titanium oxide (TiO₂), zirconia oxide (ZrO₂), barium sulfate, zinc oxide (ZnO), and polymethyl methacrylate (PMMA).

20. The display device of claim 15, wherein
the filling layer includes a filling resin in which the filling particles are dispersed, and
a refractive index of the filling resin is in a range of about 1.4 to about 1.7.
